(19) United States
(12) Patent Application Publication
(10) Pub. No.: US 2020/0154058 A1
(43) Pub. Date: May 14, 2020

(54) IMAGE SENSOR AND METHOD OF MANUFACTURING THE SAME

(71) Applicant: HUAIAN IMAGING DEVICE MANUFACTURER CORPORATION, Huaian (CN)

(72) Inventors: Fa WU, HUAIAN (CN); Shijie CHEN, HUAIAN (CN); Xiaolu HUANG, HUAIAN (CN)

(73) Assignee: HUAIAN IMAGING DEVICE MANUFACTURER CORPORATION, HUAIAN (CN)

(21) Appl. No.: 16/589,880

(22) Filed: Oct. 1, 2019

(30) Foreign Application Priority Data
Nov. 12, 2018 (CN) 201811336099.7

(51) Int. Cl. H04N 5/232; H01L 27/30

(52) U.S. Cl. CPC H04N 5/232122; H01L 27/307

(57) ABSTRACT

An image sensor comprises a pixel array, wherein at least one pixel cell in the pixel array comprises an imaging photosensitive element configured to convert a portion of incident light into charges for an image signal, and first and second phase detection photosensitive elements arranged side by side at one side of the imaging photosensitive element opposite to a light incident side and configured to convert light penetrating the imaging photosensitive element into charges for first and second phase detection signals respectively, wherein the first and second phase detection signals are used for focus detection.

### CROSS-REFERENCE TO RELATED APPLICATIONS

This application claims priority to Chinese Patent Application No. 201811336099.7, filed on Nov. 12, 2018, which is hereby incorporated by reference in its entirety.

### TECHNICAL FIELD

The present disclosure relates generally to the field of semiconductor technology, and more particularly to the field of an image sensor.

### BACKGROUND

Phase Detection Auto-Focus (PDAF) is a method for automatic focus which is currently popular. Generally, it is desirable to reserve some pairs of pixels dedicated to PDAF (briefly referred to as PDAF pixels) over photosensitive elements. A pair of pixels are shielded on either left side or right side respectively, and then a defocus degree (also referred to as out-of-focus level) of the current position of a lens is determined by comparing phase differences detected by this pair of pixels, such that a distance for which the lens should be moved and a direction in which the lens should be moved can be obtained, thereby realizing the effect of automatic focus. However, the PDAF pixels occupy positions of pixels for forming the image signal and result in a loss of the image signals, while too few PDAF pixels will affect the effect of focus. The more the PDAF pixels are provided, the faster the focus will be, but the more serious the loss of the image signals will be.

Therefore, there is a need for a new technology of PDAF focus.

### SUMMARY

One of aims of the present disclosure is to provide a new structure of an image sensor and a corresponding method of manufacture.

According to one aspect of the present disclosure, an image sensor is provided, the image sensor comprising: a pixel array, wherein at least one pixel cell in the pixel array comprises: an imaging photosensitive element configured to convert a portion of incident light into charges for an image signal; and first and second phase detection photosensitive elements arranged side by side at one side of the imaging photosensitive element opposite to a light incident side and configured to convert light penetrating the imaging photosensitive element into charges for first and second phase detection signals, respectively, wherein the first and second phase detection signals are used for focus detection.

According to another aspect of the present disclosure, a method of manufacturing an image sensor is provided, the method comprising: forming a pixel array including at least one pixel cell, wherein forming the pixel array comprises: forming, in a substrate composed of a first inorganic semiconductor material, a photodiode as an imaging photosensitive element in a pixel cell to convert a portion of incident light into charges for an image signal; and forming first and second phase detection photosensitive elements arranged side by side over a main surface at one side of the substrate opposite to a light incident side, wherein the first and second phase detection photosensitive elements convert light penetrating the imaging photosensitive element into charges for first and second phase detection signals, wherein the first and second phase detection signals are used for focus detection.

Further features of the present disclosure and advantages thereof will become apparent from the following detailed description of exemplary embodiments of the present disclosure with reference to the attached drawings.

### BRIEF DESCRIPTION OF THE DRAWINGS

The accompanying drawings, which constitute a part of the specification, illustrate embodiments of the present disclosure and, together with the description, serve to explain the principles of the present disclosure.

The present disclosure will be better understood according the following detailed description with reference of the accompanying drawings.

FIG. 1A shows a sectional view of an image sensor according to one or more exemplary embodiments of the present disclosure, and FIG. 1B shows a planar view corresponding to the image sensor as shown in FIG. 1A.

FIG. 2 illustratively shows a circuit diagram of a reading circuit in an image sensor according to one or more exemplary embodiments of the present disclosure.

FIG. 3A shows a sectional view of an image sensor according to one example of the present disclosure.

FIG. 3B shows a sectional view of an image sensor according to another example of the present disclosure.

FIG. 4 shows a flowchart of a method of manufacturing an image sensor according to one or more exemplary embodiments of the present disclosure.

FIGS. 5A-5E show sectional views of an image sensor at respective steps of the method of manufacturing the image sensor according to one or more exemplary embodiments of the present disclosure, respectively.

Note that, in the embodiments described below, in some cases the same portions or portions having similar functions are denoted by the same reference numerals in different drawings, and description of such portions is not repeated. In some cases, similar reference numerals and letters are used to refer to similar items, and thus once an item is defined in one figure, it need not be further discussed for following figures.

In order to facilitate understanding, the position, the size, the range, or the like of each structure illustrated in the drawings and the like are not accurately represented in some cases. Thus, the disclosure is not necessarily limited to the position, size, range, or the like as disclosed in the drawings and the like.

### DETAILED DESCRIPTION

Various exemplary embodiments of the present disclosure will be described in details with reference to the accompanying drawings in the following. It should be noted that the relative arrangement of the components and steps, the numerical expressions, and numerical values set forth in these embodiments do not limit the scope of the present disclosure unless it is specifically stated otherwise.

The following description of at least one exemplary embodiment is merely illustrative in nature and is in no way intended to limit this disclosure, its application, or uses. That is to say, the structure and method discussed herein are illustrated by way of example to explain different embodiments according to the present disclosure. It should be understood by those skilled in the art that, these examples, while indicating the implementations of the present disclosure, are given by way of illustration only, but not in an exhaustive way. In addition, the drawings are not necessarily drawn to scale, and some features may be enlarged to show details of some specific components.

Techniques, methods and apparatus as known by one of ordinary skill in the relevant art may not be discussed in detail, but are intended to be regarded as a part of the specification where appropriate.

In all of the examples as illustrated and discussed herein, any specific values should be interpreted to be illustrative only and non-limiting. Thus, other examples of the exemplary embodiments could have different values.

In this text, the “main surface” of a substrate means two main surfaces of the substrate (e.g. a silicon wafer) vertical to a thickness direction. The “front surface” of the substrate is directed to the main surface on which transistor(s) and metal interconnect layer(s) are formed, and the “back surface” of the substrate is directed to the main surface opposite to the front surface. The “planar view” is directed to a top view of an image sensor, and shows a graph obtained by projecting respective components of the image sensor onto a planar view that is parallel to the main surface of the substrate. The “horizontal direction” is directed to a direction that is parallel to the main surface of the substrate in the sectional view of the image sensor.

The “reading circuit” as mentioned in this text is directed to a reading circuit as included in each pixel cell, which reads the amount of charges that are obtained and transferred from a photosensitive element based on an external control signal, and outputs a corresponding signal. The present disclosure is not limited to a particular structure of the reading circuit but may employ various reading circuits known in the art as required.

Through a deep study, the inventor of the present application provides a new structure of the image sensor, in which two phase detection photosensitive elements, which are arranged side by side, are provided at one side of an imaging photosensitive element opposite to a light incident side in a normal pixel (namely a pixel for forming an image signal) of a photosensitive region of the image sensor, and light penetrating the imaging photosensitive element is used for carrying out phase detection, so as to increase the utilization rate of light. In addition, the normal pixel may be utilized for phase detection without having to provide special PDAF pixel(s) in the photosensitive region, which thus reduces a loss of the image signal and can increase the number of the phase detection photosensitive elements, thereby enhancing the sensitivity of phase detection.

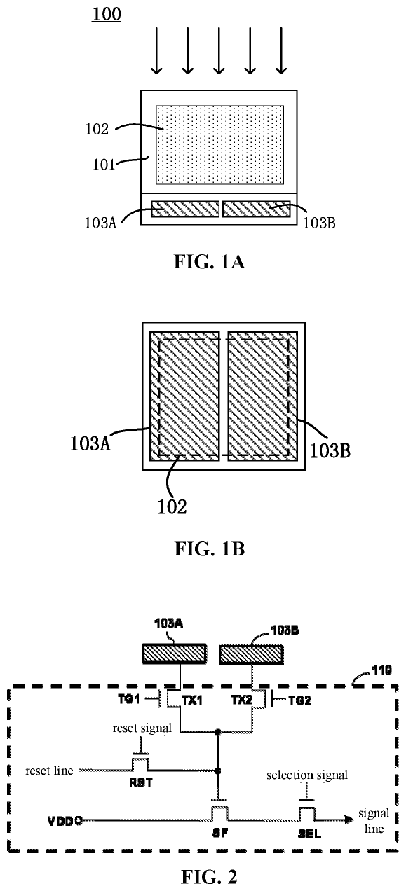

By combining FIGS. 1A to 1B and by taking a back-side illumination CMOS image sensor as an example, a structure of the image sensor according to the present disclosure is described in detail below. Those skilled in the art can understand that, the present disclosure is not limited to the structure shown in the figures, but can be modified according to its operating principle to be adaptive for other image sensors structures. For example, the present disclosure may be also applied to a front-side illumination image sensor.

FIG. 1A shows a sectional view of an image sensor according to one or more exemplary embodiments of the present disclosure, and FIG. 1B shows a planar view of the image sensor as shown in FIG. 1A. Notice that, there are possibly other components in an actual image sensor that are manufactured previously/subsequently. To prevent main points of the present disclosure from being obscured, no other components are shown in the drawings or discussed in this text.

FIG. 1A shows one pixel cell in the pixel array of the image sensor. Notice that, a plurality of pixel cells having identical structures may be arranged in the pixel array as required, or all the pixel cells are allowed to have this new structure, for which no limit is made in the present disclosure.

As shown in FIG. 1A, the pixel cell 100 includes an imaging photosensitive element 102 formed in a substrate 101, which converts a portion of incident light into charges for an image signal. The figure shows a structure in which a back surface of the substrate faces upward, and light is incident from the above as shown by arrows in the figure. In some embodiments, the imaging photosensitive element 102 may be a photodiode (PD) formed of an inorganic semiconductor material. For example, the substrate 101 may be a simple semiconductor wafer, e.g. a silicon wafer, and the imaging photosensitive element 102 is formed by doping the P-type substrate 101 to form an N-type region. Namely, the N-type region formed by doping is an N region of the imaging photosensitive element 102, and a portion of the P-type substrate in contact with the N region serves as a P region of the imaging photosensitive element 102. However, the present disclosure makes no limit for the structure of the imaging photosensitive element 102 as shown in the figure. For example, in some embodiments, the imaging photosensitive element 102 may be a pinned PD, namely the imaging photosensitive element 102 may further include a P-type pinned layer formed on the N region. In addition, although the substrate 101 is drawn as a simple block substrate in the figure for the sake of brevity, the present disclosure is not limited to this. Substrate 101 may be made of any semiconductor material (e.g. Si, SiC, and so on) adaptive for the image sensor. In some embodiments, the substrate 101 may also be a Silicon-on-Insulator (SOI) or other composite substrates. A doping type or other doping situation of the substrate 101 is not limited either. Those skilled in the art will understand that the substrate 101 is not limited at all but may be chosen according to actual applications. Other members of a semiconductor device may also be formed in and below the substrate 101, such as other members formed in the early/subsequent processing steps. Moreover, the present disclosure makes no limit for the type of the image sensor, for example, both a front-side illumination (FSI) type and a back-side illumination (BSI) type are applicable.

As shown in FIG. 1A, the pixel cell 100 further includes phase detection photosensitive elements 103A and 103B arranged side by side. The phase detection photosensitive elements 103A and 103B are located at one side (namely, lower side as shown in FIG. 1A) of the imaging photosensitive element 102 opposite to a light incident side (namely, upper side as shown in FIG. 1A), and are configured to convert light penetrating the imaging photosensitive element 102 into charges for first and second phase detection signals respectively, wherein the first and second phase detection signals are used for focus detection. In this text, “arranged side by side” means both phase detection photosensitive elements do not overlap each other, but do not mean that both of them should be completely aligned with each other. As shown in the figure, the phase detection photosensitive elements 103A and 103B are disposed in a dielectric layer, and separated from the imaging photosensitive element 102 in the substrate 101.

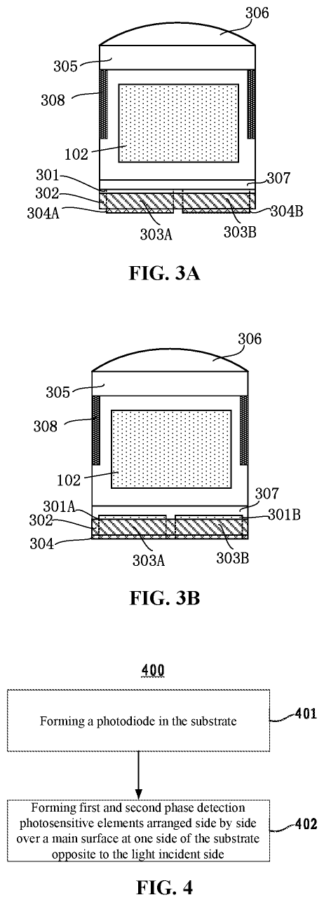

In some embodiments, as described in detail below in combination with FIGS. 3A and 3B, the aforementioned phase detection photosensitive elements 103A and 103B may be organic photoelectric conversion elements, which each include an upper electrode, an organic photoelectric conversion film, and a lower electrode.

In some other embodiments, the aforementioned phase detection photosensitive elements 103A and 103B may be photodiodes formed of an inorganic semiconductor material. For example, the inorganic semiconductor material may be a material that can convert incident light (in particular red light) into an electrical signal. In some examples, to improve the sensitivity of phase detection, the inorganic semiconductor material of phase detection photosensitive elements 103A and 103B may be a semiconductor material that has a higher photoelectric conversion efficiency than the material of the substrate. For example, if the substrate has a material of Si, the inorganic semiconductor material of the phase detection photosensitive elements may be Ge, SiGe, or the like.

FIG. 1B is a schematic planar view corresponding to FIG. 1A, and shows the locational relationship of various components on the planar view. The dashed line in FIG. 1B denotes the imaging photosensitive element 102 overlapping phase detection photosensitive elements 103A and 103B. As can be seen from the planar view of FIG. 1B, the phase detection photosensitive element 103A overlaps a left portion of the imaging photosensitive element 102, and the phase detection photosensitive element 103B overlaps a right portion of the imaging photosensitive element 102. Therefore, the phase detection photosensitive element 103A receives light penetrating the left portion of the imaging photosensitive element 102 so as to generate a first phase detection signal. Similarly, the phase detection photosensitive element 103B receives light penetrating the right portion of imaging photosensitive element 102, so as to generate a second phase detection signal. Then, focus detection is carried out by using a pair of phase detection signals obtained by phase detection photosensitive elements 103A and 103B. Specifically speaking, the pair of phase detection signals may be utilized to determine a focus state, so as to determine a distance for which a lens should be moved and a direction in which the lens should be moved.

Phase information is obtained by utilizing residual ray of light that penetrates the imaging photosensitive element, thus the utilization rate of light is improve. In addition, since normal pixel cells can be utilized to carry out phase detection without having to arrange special PDAF pixels in the photosensitive region, the number of phase detection photosensitive elements can be substantially increased to improve the focus efficiency and a loss of signals which results from the arrangement of special PDAF pixels can be avoided. Therefore, the sensitivity of phase detection can be improved without any loss of the image signals.

Those skilled in the art can understand that, although FIG. 1B shows phase detection photosensitive elements 103A and 103B, which occupy both left and right halves respectively, for carrying out focus detection, the present disclosure is not limited to this. That is, the present disclosure does not limit the locational relationship between two phase detection photosensitive elements. In practice, those skilled in the art may make any arrangement as required, as long as the difference between the phase information of the two phase detection photosensitive elements can be effectively embodied.

In addition, the pixel cell 100 in FIG. 1A may further include shallow/deep trench separators (not shown) located at edges thereof, for separating individual pixel cells. Those skilled in the art will also understand that, there is also transistor(s) or other element(s) in the pixel cell for use in the reading circuit or the like. To prevent the subject matter of the present disclosure from being obscured, descriptions for these elements are omitted here.

FIG. 2 illustratively shows a circuit diagram of a reading circuit in the image sensor according to one or more exemplary embodiments of the present disclosure.

The pixel cell 100 in FIG. 1A may further include a reading circuit 110 for phase detection photosensitive elements 103A and 103B. The reading circuit 110 may operate in a first mode or a second mode. In the first mode, the reading circuit 110 reads phase detection photosensitive elements 103A and 103B, respectively, to generate first and second phase detection signals respectively for carrying out focus detection. In the second mode, the reading circuit 110 reads both phase detection photosensitive elements 103A and 103B, so as to generate a sum of the first and second phase detection signals for enhancing the image signal. That is, the first and second phase detection signals are added to an image signal generated by imaging photosensitive element 102 to form an enhanced image signal. In this way, the quantum efficiency may be increased.

FIG. 2 gives a typical example of reading circuit 110 which is a variant of the 4T reading circuit structure as currently well-known, wherein mainly, a first transfer transistor TX1 and a second transfer transistor TX2 are respectively arranged for phase detection photosensitive elements 103A and 103B and connected collectively to the subsequent reading circuit.

As shown in FIG. 2, one of source and drain of the first transfer transistor TX1 and one of source and drain of the second transfer transistor TX2 are connected to phase detection photosensitive elements 103A and 103B, respectively, and the other one of source and drain of the first transfer transistor TX1 and the other one of source and drain of the second transfer transistor TX2 are connected together. Gates of first transfer transistor TX1 and second transfer transistor TX2 are connected to a first control signal TG1 and a second control signal TG2, respectively. The first control signal TG1 and the second control signal TG2 may control the turn-on and turn-off of the first transfer transistor TX1 and the second transfer transistor TX2 respectively, such that the first transfer transistor TX1 and the second transfer transistor TX2 may be separately turned on, thereby outputting a first phase detection signal and a second phase detection signal respectively. That is, focus detection is carried out by operating in the first mode. In some embodiments, the first control signal TG1 and the second control signal TG2 may turn on the first transfer transistor TX1 and the second transfer transistor TX2 simultaneously, so as to read a sum of the first and second phase detection signals. That is, operating in the second mode is used for sensing the ray of light and enhancing the image signal.

In some embodiments, the reading circuits of imaging photosensitive elements as shown in FIG. 1A may also share one or more of a reset transistor RST, a source follower transistor SF and a selection transistor SEL in reading circuit 110 of FIG. 2. Certainly, the present disclosure does not limit the specific structure of the reading circuit used for imaging photosensitive element 102 and phase detection photosensitive elements 103A and 103B. Those skilled in the art can understand that the exiting reading circuit may be adaptively modified based on the aforementioned idea of FIG. 2, and all these variants are included in the scope of the present disclosure.

By referring to FIGS. 3A and 3B, the structure and operating principle of the image sensor according to the exemplary embodiments of the present disclosure will be explained below in more detail and completely.

FIG. 3A shows a sectional view of the image sensor according to one example of the present disclosure, wherein all the phase detection photosensitive elements are organic photoelectric conversion elements. For brevity, repetitive descriptions for the same components as in FIGS. 1A and 1B will be omitted.

The pixel cell shown in FIG. 3A includes a color filter 305 and a micro lens 306. As shown in FIG. 3A, the color filter 305 is formed over a back surface of the substrate, and a micro lens 306 is formed over the color filter 305. Light enters into the pixel from above the micro lens 306. Therefore, both the color filter 305 and micro lens 306 are located in a light path before light is incident onto the imaging photosensitive element 102.

In some embodiments, the color filter 305 may be a red color filter. Those skilled in the art should understand that, in the pixel cell, the color filter may be generally a red, green or blue color filter. When the color filter is a red color filter, light penetrating the imaging photosensitive element 102 is red light. Compared with green and blue light, red light has a longer wavelength, such that the penetration ratio at which red light penetrates the imaging photosensitive element is greater than those of green light and blue light. Therefore, arranging the color filter as a red color filter may make the light intensity of the residual ray of light that penetrates the imaging photosensitive element and reaches the phase detection photosensitive elements to be stronger, such that the accuracy of the phase detection signal can be enhanced and the focus efficiency can be increased.

FIG. 3A further shows specific structures of phase detection photosensitive elements 303A and 303B. Phase detection photosensitive element 303A is an organic photoelectric conversion element, including upper electrode 301, lower electrode 304A, and organic photoelectric conversion film 302 located between the upper and lower electrodes. As shown in FIG. 3A, the upper electrode 301 is closer to imaging photosensitive element 102 than the lower electrode 304A, and the upper electrode 301 is transparent to light penetrating the imaging photosensitive element 102. Therefore, light that penetrates the imaging photosensitive element 102 and enters into phase detection photosensitive element 303A may penetrate the transparent upper electrode 301 and enter into the organic photoelectric conversion film 302 which whereby carries out photoelectric conversion and generates charges for the first phase detection signal. Phase detection photosensitive element 303B is also an organic photoelectric conversion element, and has a similar structure. In addition, phase detection photosensitive elements 303A and 303B are separated from the imaging photosensitive element 102 by a interlayer dielectric layer 307 on the front surface of the substrate, and the pixel cell further includes deep trench separator(s) 308 located at edges for separating individual pixel cells.

As shown in FIG. 3A, the phase detection photosensitive elements 303A and 303B share the upper electrode and the organic photoelectric conversion film, namely upper electrode 301 and organic photoelectric conversion film 302 that are integrally formed as shown in the figure. In some embodiments, the phase detection photosensitive elements in all the pixel cells in the pixel array may share an upper electrode of a layer and an organic photoelectric conversion film of a layer. In addition, in some alternative embodiments, phase detection photosensitive elements 303A and 303B or all the phase detection photosensitive elements may also share a lower electrode instead of the upper electrode. By utilizing such a structure of sharing the upper electrode, the lower electrode and/or the organic photoelectric conversion film, there is no need to carry out a patterning process for the upper electrode, the lower electrode or the organic photoelectric conversion film with respect to respective phase detection photosensitive elements in the manufacturing process, which thus simplifies the manufacturing process.

Regions of phase detection photosensitive elements 303A and 303B are defined by separated lower electrodes 304A and 304B respectively, namely only regions covered by lower electrodes 304A and 304B, as denoted by the dashed line in FIG. 3A. Since the phase detection photosensitive elements 303A and 303B as shown in FIG. 3A are organic photoelectric conversion elements, only photo-charges generated by portions, to which an electric field is applied, can be outputted, and thus only portions clamped by the upper and lower electrodes may be regarded as the phase detection photosensitive element. Since upper electrode 301 in FIG. 3A covers the entire pixel region, the regions of the phase detection photosensitive elements are defined by the lower electrodes.

In some embodiments, the organic photoelectric conversion film 302 may include an active layer having conjugated polymer compounds and fullerene derivatives.

In some embodiments, although not shown in the drawings, the phase detection photosensitive elements 303A and 303B may further include various known functional layers such as an electron injection layer, a hole transport layer, an electron blocking layer, a layer that improves flatness at the time of evaporation of an anode, a layer that protects an active layer from solvent corrosion in the case of manufacturing an anode with a coating method, and/or a layer that suppresses deterioration of an active layer.

In addition, in the case of employing the structure as shown in FIG. 3A, the first and second transfer transistors TX 1 and TX 2 in FIG. 2 described above may be connected to the separated lower electrodes 304A and 304B, respectively.

According to the structure of the pixel cell as shown in FIG. 3A, light enters the pixel from above the micro lens 306. Then, the light enters the imaging photosensitive element 102 through the color filter 305. The light penetrating the left portion of the imaging photosensitive element 102 enters the phase detection photosensitive element 303A and generates charges for the first phase detection signal. Similarly, the light penetrating the right portion of the imaging photosensitive element 102 enters the phase detection photosensitive element 303B and generates charges for the second phase detection signal. Then, focus detection is carried out by using the obtained pair of phase detection signals.

An example in which the phase detection photosensitive elements 303A and 303B share the upper electrode is shown in FIG. 3A, and an example in which the phase detection photosensitive elements 303A and 303B share the lower electrode according to one or more embodiments of the present application will be described below with reference to FIG. 3B. FIG. 3B illustrates a sectional view of the image sensor according to another example of the present disclosure, in which all the phase detection photosensitive elements are organic photoelectric conversion elements. As shown in FIG. 3B, the phase detection photosensitive elements 303A and 303B share the lower electrode 304 and the organic photoelectric conversion film 302, but respectively employ separated upper electrodes 301A and 301B. Similar to that described above with reference to FIG. 3A, the regions of phase detection photosensitive elements 303A and 303B in FIG. 3B may be defined by separated upper electrodes 301A and 301B, respectively.

In addition, as shown in FIG. 3B, the lower electrode 304 covers the entire region of imaging photosensitive element 102 and can reflect the light penetrating the imaging photosensitive element 102. For example, the lower electrode 304 may be made of a metal that reflects light. Since all the light penetrating the imaging photosensitive element 102 is reflected completely, there is no light that influences the components below the lower electrode, and the utilization efficiency of light can be further improved.

FIG. 4 shows a flowchart of a method 400 of manufacturing an image sensor according to one or more exemplary embodiments of the present disclosure. The image sensor comprises a pixel array comprising at least one new pixel cell according to the present disclosure. The method 400 includes steps of forming a pixel array, comprising steps 401 and 402 described below.

As shown in FIG. 4, at step 401, a photodiode is formed in a substrate composed of a first inorganic semiconductor material as an imaging photosensitive element in the pixel cell to convert a portion of incident light into charges for an image signal.

At step 402, the first and second phase detection photosensitive elements arranged side by side are formed over a main surface at one side of the substrate opposite to a light incident side, wherein the first and second phase detection photosensitive elements convert light penetrating the imaging photosensitive element into charges for first and second phase detection signals, and the first and second phase detection signals are used for focus detection.

In some embodiments, the step of forming the first and second phase detection photosensitive elements comprises: forming an interlayer dielectric layer over a main surface at one side of the substrate opposite to the light incident side; etching the interlayer dielectric layer to form groove(s); and forming, in the groove(s), all or at least one of the components of the first and second phase detection photosensitive elements. In some embodiments, upper electrode(s) of the first and second phase detection photosensitive elements may be formed in the groove(s), for example, when the structure shown in FIG. 3B is manufactured. Specifically speaking, the groove(s) is(are) filled with a conductive material to form the upper electrode(s), then a planarization process is carried out to remove the conductive material outside the groove, and then an organic photoelectric conversion film and a lower electrode are sequentially formed over the planarized interlayer dielectric layer and upper electrode(s).

In some embodiments, the organic photoelectric conversion film is fabricated by means of coating at a room temperature and then annealing at a temperature of 100° C. to 200° C.

As previously stated, those skilled in the art will understand that there will be other steps before and after steps 401 and 402 for fabricating other elements of the image sensor, and descriptions of such steps are omitted herein so as not to obscure the subject matter of the present disclosure.

In addition, those skilled in the art will understand that the order of steps 401 and 402 shown in FIG. 4 is merely exemplary, and not intended to limit the present disclosure. The order of performing steps 401 and 402 is not limited and may be determined according to actual circumstances. For example, the phase detection photosensitive element(s) may be formed before forming the photodiode. In addition, steps 401 and 402 may be alternately performed, for example, a portion of the steps of forming the phase detection photosensitive element(s) is performed before forming the photodiode, and then the remaining steps for forming the phase detection photosensitive element(s) are performed. In addition, a portion of the operations in steps 401 and 402 may be performed simultaneously or concurrently with other operations.

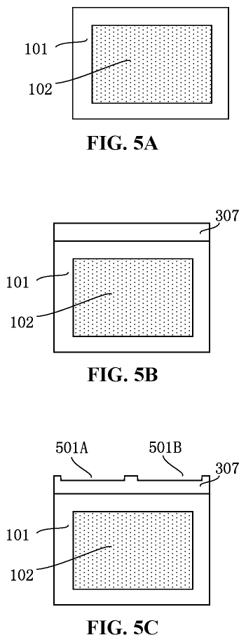

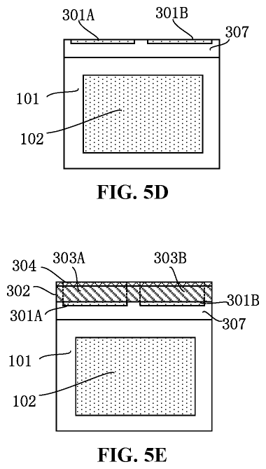

A specific example of a method of manufacturing an image sensor according to one exemplary implementation of the present disclosure will be described in detail below by taking FIGS. 5A to 5E as an example. The present example is particularly applicable to a back-side illumination CMOS image sensor. Note that this example is not intended to constitute a limitation to the present disclosure.

FIGS. 5A to 5E show schematic sectional views of the image sensor at various steps of the example of the method, respectively. The manufacturing method will be described specifically with respect to the pixel structure shown in FIG. 3B. Note that the steps described below are all performed from the front surface of the substrate, and therefore, as compared with the aforementioned respective structural views in which the back surface of the substrate faces upward, the structures in FIGS. 5A to 5E below are turned upside down so that the front surface of the substrate faces upward.

At FIG. 5A, for example, an N-type region may be formed in substrate 101 (e.g., a P-type substrate of single crystal silicon) by a conventional operation such as ion implantation, thereby forming a photodiode as imaging photosensitive element 102 in a pixel cell.

At FIG. 5B, an interlayer dielectric layer 307 is formed on the front surface of substrate 101 (light is incident from the back surface of the substrate). For example, the interlayer dielectric layer 307 may be formed by depositing a dielectric material such as oxide on the front surface of the substrate.

At FIG. 5C, the interlayer dielectric layer 307 may be etched to form grooves 501A and 501B. The grooves may be etched by various conventional means.

At FIG. 5D, upper electrodes 301A and 301B of the first and second phase detection photosensitive elements may be formed in grooves 501A and 501B, respectively. Specifically, grooves 501A and 501B are filled with a conductive material by a deposition process, and then a planarization process is carried out to remove the conductive material outside the grooves. Upper electrodes 301A and 301B are transparent to incident light, and may be formed of ITO, for example. Note that, other manners may be selected to fabricate the upper electrode according to the material characteristics of the upper electrode and etc., without being limited to the processes shown in FIGS. 5C and 5D.

At FIG. 5E, organic photoelectric conversion film 302 and lower electrode 304 may be sequentially formed over the planarized interlayer dielectric layer 307 and upper electrodes 301A and 301B. As descripted above with reference to FIG. 3B, in some embodiments, all the phase detection photosensitive elements in the pixel array share the organic photoelectric conversion film 302 and the lower electrode 304. The lower electrode 304 covers the entire imaging region and can reflect light that penetrates the imaging photosensitive element 102.

In some embodiments, the organic photoelectric conversion film 302 may be fabricated by coating at a room temperature and then annealing at a temperature of 100° C. to 200° C.

In addition, the fabrication of the color filter and micro lens shown in FIG. 3B is omitted for the sake of brevity. Those skilled in the art will understand that the color filter and micro lens may be fabricated by a variety of conventional means. Those skilled in the art will understand that the present disclosure further includes any other processes and structures necessary to form an image sensor in addition to those as illustrated.

Those skilled in the art will understand that image sensors according to other embodiments of the present disclosure may be fabricated by employing methods similar to those shown in FIGS. 5 A to 5E above with only some adaptive modifications.

The terms “front,” “back,” “top,” “bottom,” “over,” “under” and the like, as used herein, if any, are used for descriptive purposes and not necessarily for describing permanent relative positions. It should be understood that such terms are interchangeable under appropriate circumstances such that the embodiments of the disclosure described herein are, for example, capable of operation in other orientations than those illustrated or otherwise described herein.

The term “exemplary”, as used herein, means “serving as an example, instance, or illustration”, rather than as a “model” that would be exactly duplicated. Any implementation described herein as exemplary is not necessarily to be construed as preferred or advantageous over other implementations. Furthermore, there is no intention to be bound by any expressed or implied theory presented in the preceding technical field, background, summary or detailed description.

The term “substantially”, as used herein, is intended to encompass any slight variations due to design or manufacturing imperfections, device or component tolerances, environmental effects and/or other factors. The term “substantially” also allows for variation from a perfect or ideal case due to parasitic effects, noise, and other practical considerations that may be present in an actual implementation.

In addition, the foregoing description may refer to elements or nodes or features being “connected” or “coupled” together. As used herein, unless expressly stated otherwise, “connected” means that one element/node/feature is electrically, mechanically, logically or otherwise directly joined to (or directly communicates with) another element/node/feature. Likewise, unless expressly stated otherwise, “coupled” means that one element/node/feature may be mechanically, electrically, logically or otherwise joined to another element/node/feature in either a direct or indirect manner to permit interaction even though the two features may not be directly connected. That is, “coupled” is intended to encompass both direct and indirect joining of elements or other features, including connection with one or more intervening elements.

In addition, certain terminology, such as the terms “first”, “second” and the like, may also be used in the following description for the purpose of reference only, and thus are not intended to be limiting. For example, the terms “first”, “second” and other such numerical terms referring to structures or elements do not imply a sequence or order unless clearly indicated by the context.

Further, it should be noted that, the terms “comprise”, “include”, “have” and any other variants, as used herein, specify the presence of stated features, integers, steps, operations, elements, and/or components, but do not preclude the presence or addition of one or more other features, integers, steps, operations, elements, components, and/or groups thereof.

In this disclosure, the term “provide” is intended in a broad sense to encompass all ways of obtaining an object, thus the expression “providing an object” includes but is not limited to “purchasing”, “preparing/manufacturing”, “disposing/arranging”, “installing/assembling”, and/or “ordering” the object, or the like.

Furthermore, those skilled in the art will recognize that boundaries between the above described operations are merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments. However, other modifications, variations and alternatives are also possible. The description and drawings are, accordingly, to be regarded in an illustrative rather than in a restrictive sense.

Although some specific embodiments of the present disclosure have been described in detail with examples, it should be understood by a person skilled in the art that the above examples are only intended to be illustrative but not to limit the scope of the present disclosure. The embodiments disclosed herein can be combined arbitrarily with each other, without departing from the scope and spirit of the present disclosure. It should be understood by a person skilled in the art that the above embodiments can be modified without departing from the scope and spirit of the present disclosure. The scope of the present disclosure is defined by the attached claims.

What is claimed is:

1. An image sensor, comprising:
a pixel array, wherein at least one pixel cell in the pixel array comprises:
an imaging photosensitive element configured to convert a portion of incident light into charges for an image signal; and
first and second phase detection photosensitive elements arranged side by side at one side of the imaging photosensitive element opposite to a light incident side and configured to convert light penetrating the imaging photosensitive element into charges for first and second phase detection signals, respectively, wherein the first and second phase detection signals are used for focus detection.

2. The image sensor according to claim 1, wherein the pixel cell further comprises a reading circuit configured to operate in a first mode or a second mode; wherein in the first mode the reading circuit reads the first and second phase detection photosensitive elements, respectively, to generate the first and second phase detection signals, respectively, for carrying out the focus detection; and wherein in the second mode the reading circuit reads both the first and second phase detection photosensitive elements to generate a sum of the first and second phase detection signals for enhancing an image signal.

3. The image sensor according to claim 2, wherein the reading circuit includes first and second transfer transistors, wherein one of a source and a drain of the first transfer transistor and one of a source and a drain of the second transfer transistor are connected to the first and second phase detection photosensitive elements, respectively, wherein the other one of the source and the drain of the first transfer transistor and the other one of the source and the drain of the second transfer transistor are connected together, and wherein gates of the first and second transfer transistors are connected to first and second control signals, respectively.

4. The image sensor according to claim 1, wherein, the imaging photosensitive element includes a photodiode formed of a first inorganic semiconductor material.

5. The image sensor according to claim 1, wherein, each of the first and second phase detection photosensitive elements includes an upper electrode, a lower electrode, and an organic photoelectric conversion film between the upper electrode and the lower electrode, wherein the upper electrode is closer to the imaging photosensitive element than the lower electrode, and the upper electrode is transparent to light penetrating the imaging photosensitive element.

6. The image sensor according to claim 5, wherein, the first and second phase detection photosensitive elements share the organic photoelectric conversion film.

7. The image sensor according to claim 6, wherein, the first and second phase detection photosensitive elements further share one of the upper electrode and the lower electrode, and the other one of the upper electrode and the lower electrode of the first phase detection photosensitive element and the other one of the upper electrode and the lower electrode of the second phase detection photosensitive element are separated from each other.

8. The image sensor according to claim 7, wherein, regions of the first and second phase detection photosensitive elements are defined by the separated lower or upper electrode, respectively.

9. The image sensor according to claim 7, wherein the first and second phase detection photosensitive elements further share the lower electrode, wherein the regions of the first and second phase detection photosensitive elements are defined by the separated upper electrodes, and wherein the lower electrode covers an entire region of the imaging photosensitive element and can reflect light penetrating the imaging photosensitive element.

10. The image sensor according to claim 4, wherein each of the first and second phase detection photosensitive elements includes a photodiode formed of a second inorganic semiconductor material, wherein a photoelectric conversion efficiency of the second inorganic semiconductor material is higher than a photoelectric conversion efficiency of the first inorganic semiconductor material.

11. A method for manufacturing an image sensor, comprising:
forming a pixel array including at least one pixel cell, wherein forming the pixel array comprises:
forming, in a substrate composed of a first inorganic semiconductor material, a photodiode as an imaging photosensitive element in a pixel cell to convert a portion of incident light into charges for an image signal; and
forming first and second phase detection photosensitive elements arranged side by side over a main surface at one side of the substrate opposite to a light incident side,
wherein the first and second phase detection photosensitive elements convert light penetrating the imaging photosensitive element into charges for first and second phase detection signals, wherein the first and second phase detection signals are used for focus detection.

12. The method according to claim 11, further comprising: forming a reading circuit at one side of the substrate opposite to the light incident side, wherein the reading circuit operates in a first mode or a second mode, wherein in the first mode the reading circuit reads the first and second phase detection photosensitive elements, respectively, to generate first and second phase detection signals, respectively, for carrying out the focus detection; and wherein in the second mode the reading circuit reads both the first and second phase detection photosensitive elements to generate a sum of the first and second phase detection signals for enhancing an image signal.

13. The method according to claim 12, wherein the reading circuit includes first and second transfer transistors, wherein one of a source and a drain of the first transfer transistor and one of a source and a drain of the second transfer transistor are connected to the first and second phase detection photosensitive elements, respectively, wherein the other one of the source and the drain of the first transfer transistor and the other one of the source and the drain of the second transfer transistor are connected together, and wherein gates of the first and second transfer transistors are connected to first and second control signals, respectively.

14. According to the method of claim 11, wherein, each of the first and second phase detection photosensitive elements includes an upper electrode, a lower electrode, and an organic photoelectric conversion film between the upper electrode and the lower electrode, wherein the upper electrode is closer to the imaging photosensitive element than the lower electrode, and the upper electrode is transparent to light penetrating the imaging photosensitive element.

15. The method according to claim 14, wherein, the first and second phase detection photosensitive elements share the organic photoelectric conversion film.

16. The method according to claim 15, wherein, the first and second phase detection photosensitive elements further share one of the upper electrode and the lower electrode, and the other one of the upper electrode and the lower electrode of the first phase detection photosensitive element and the other one of the upper electrode and the lower electrode of the second phase detection photosensitive element are separated from each other.

17. The method according to claim 16, wherein, regions of the first and second phase detection photosensitive elements are defined by the separated lower or upper electrode, respectively.

18. The method according to claim 16, wherein the first and second phase detection photosensitive elements further share the lower electrode, wherein the regions of the first and second phase detection photosensitive elements are defined by the separated upper electrodes, and wherein the lower electrode covers the an entire region of the imaging photosensitive element and can reflect light penetrating the imaging photosensitive element.

19. The method according to claim 11, wherein each of the first and second phase detection photosensitive elements includes a photodiode formed of a second inorganic semiconductor material, wherein a photoelectric conversion efficiency of the second inorganic semiconductor material is higher than that of the first inorganic semiconductor material.

20. The method according to claim 11, wherein, the step of forming the first and second phase detection photosensitive elements includes:
forming an interlayer dielectric layer over a main surface at one side of the substrate opposite to the light incident side;
etching the interlayer dielectric layer to form a groove; and
forming, in the groove, all or at least one of components of the first and second phase detection photosensitive elements.
